(19) United States
(12) Patent Application Publication
(10) Pub. No.: US 2008/0095981 A1
(43) Pub. Date: Apr. 24, 2008

(54) Molecular Electronic Device Fabrication Methods and Structures

(75) Inventors: Julian Carter, Cambridgeshire (GB); Haydn Gregory, Cambridge (GB); Martin Cacheiro, Ames (ES)

Correspondence Address: MARSHALL, GERSTEIN & BORUN LLP, 233 S. WACKER DRIVE, SUITE 6300, SEARS TOWER, CHICAGO, IL, 60606, US

(73) Assignee: CAMBRIDGE DISPLAY TECNOLOGY LIMITED, Cambridgeshire (GB)

(21) Appl. No.: 10/588,050

(22) PCT Filed: Feb. 7, 2005
(86) PCT No.: PCT/GB05/00429

§ 371 Date: Apr. 13, 2007

(30) Foreign Application Priority Data
Feb. 5, 2004 (GB) 04002559.9

(51) Int. Cl. B05D 5/12; G03F 7/00; B32B 3/00

(52) U.S. Cl. 428/141; 427/58; 430/311

(57) ABSTRACT

A method of fabricating a molecular electronic device, the method comprising: fabricating a substrate having a plurality of banks defining wells for the deposition of molecular material; and depositing molecular electronic material into said wells, dissolved in a solvent, using a droplet deposition technique, to fabricate said device; wherein a said bank has a face, defining an edge of said well, at an angle to a base of the well of greater than a contact angle of said solvent with said bank face; and wherein a height of a said bank above a said base of a said well is less than 2 μm, and more preferably less than 1.5 μm.

### BACKGROUND OF THE INVENTION

1. Field of the Invention

This invention relates generally to improved methods of fabricating molecular electronic devices, in particular organic electronic devices such as organic light emitting diodes (OLEDs) by droplet deposition techniques such as ink jet printing. The invention also relates to molecular device substrates fabricated by and/or use in such methods.

2. Related Technology

Organic light emitting diodes (OLEDs) are a particularly advantageous form of electro-optic display. They are bright, colorful, fast-switching, provide a wide viewing angle and are easy and cheap to fabricate on a variety of substrates. Organic (which here includes organometallic) LEDs may be fabricated using either polymers or small molecules in a range of colors (or in multi-colored displays), depending upon the materials used. A typical OLED device comprises two layers of organic material, one of which is a layer of light emitting material such as a light emitting polymer (LEP), oligomer or a light emitting low molecular weight material, and the other of which is a layer of a hole transporting material such as a polythiophene derivative or a polyaniline derivative.

Organic LEDs may be deposited on a substrate in a matrix of pixels to form a single or multi-color pixellated display. A multi-colored display may be constructed using groups of red, green, and blue emitting pixels. So-called active matrix displays have a memory element, typically a storage capacitor and a transistor, associated with each pixel whilst passive matrix displays have no such memory element and instead are repetitively scanned to give the impression of a steady image.

FIG. 1 shows a vertical cross section through an example of an OLED device 100. In an active matrix display part of the area of a pixel is occupied by associated drive circuitry (not shown in FIG. 1). The structure of the device is somewhat simplified for the purposes of illustration.

The OLED 100 comprises a substrate 102, typically 0.7 mm or 1.1 mm glass but optionally clear plastic, on which an anode layer 106 has been deposited. The anode layer typically comprises around 150 nm thickness of ITO (indium tin oxide), over which is provided a metal contact layer, typically around 500 nm of aluminium, sometimes referred to as anode metal. Glass substrates coated with ITO and contact metal may be purchased from Coming, USA. The contact metal (and optionally the ITO) is patterned as desired, and so that it does not obscure the display, by a conventional process of photolithography followed by etching.

A substantially transparent hole transport layer 108a is provided over the anode metal, followed by an electroluminescent layer 108b. Banks 112 may be formed on the substrate, for example from positive or negative photoresist material, to define wells 114 into which these active organic layers may be selectively deposited, for example by a droplet deposition or inkjet printing technique. The wells thus define light emitting areas or pixels of the display.

A cathode layer 110 is then applied by, say, physical vapor deposition. A cathode layer typically comprises a low work function metal such as calcium or barium covered with a thicker, capping layer of aluminum and optionally including an additional layer immediately adjacent the electroluminescent layer, such as a layer of lithium fluoride, for improved electron energy level matching. Mutual electrical isolation of cathode lines may achieved through the use of cathode separators (element 302 of FIG. 3b). Typically a number of displays are fabricated on a single substrate and at the end of the fabrication process the substrate is scribed, and the displays separated before an encapsulating can is attached to each to inhibit oxidation and moisture ingress.

Organic LEDs of this general type may be fabricated using a range of materials including polymers, dendrimers, and so-called small molecules, to emit over a range of wavelengths at varying drive voltages and efficiencies. Examples of polymer-based OLED materials are described in WO90/13148, WO95/06400 and WO99/48160; examples of dendrimer-based materials are described in WO 99/21935 and WO 02/067343; and examples of small molecule OLED materials are described in U.S. Pat. No. 4,539,507. The aforementioned polymers, dendrimers and small molecules emit light by radiative decay of singlet excitons (fluorescence). However, up to 75% of excitons are triplet excitons which normally undergo non-radiative decay. Electroluminescence by radiative decay of triplet excitons (phosphorescence) is disclosed in, for example, “Very high-efficiency green organic light-emitting devices based on electrophosphorescence” M. A. Baldo, S. Lamansky, P. E. Burrows, M. E. Thompson, and S. R. Forrest Applied Physics Letters, Vol. 75(1) pp. 4-6, Jul. 5, 1999. In the case of a polymer-based OLED layers 108 comprise a hole transport layer 108a and a light emitting polymer (LEP) electroluminescent layer 108b. The electroluminescent layer may comprise, for example, around 70 nm (dry) thickness of PPV (poly(p-phenylenevinylene)) and the hole transport layer, which helps match the hole energy levels of the anode layer and of the electroluminescent layer, may comprise, for example, around 50-200 nm, preferably around 150 nm (dry) thickness of PEDOT:PSS (polystyrene-sulphonate-doped polyethylene-dioxythiophene).

FIG. 2 shows a view from above (that is, not through the substrate) of a portion of a three-color active matrix pixellated OLED display 200 after deposition of one of the active color layers. The figure shows an array of banks 112 and wells 114 defining pixels of the display.

FIG. 3a shows a view from above of a substrate 300 for inkjet printing a passive matrix OLED display. FIG. 3b shows a cross-section through the substrate of FIG. 3a along line Y-Y′.

Referring to FIGS. 3a and 3b, the substrate is provided with a plurality of cathode undercut separators 302 to separate adjacent cathode lines (which will be deposited in regions 304). A plurality of wells 308 is defined by banks 310, constructed around the perimeter of each well 308 and leaving an anode layer 306 exposed at the base of the well. The edges or faces of the banks are tapered onto the surface of the substrate as shown, heretofore at an angle of between 10 and 40 degrees. The banks present a hydrophobic surface in order that they are not wetted by the solution of deposited organic material and thus assist in containing the deposited material within a well. This is achieved by treatment of a bank material such as polyimide with an O₂/CF₄ plasma as disclosed in EP 0989778. Alternatively, the plasma treatment step may be avoided by use of a fluorinated material such as a fluorinated polyimide as disclosed in WO 03/083960.

As previously mentioned, the bank and separator structures may be formed from resist material, for example using a positive (or negative) resist for the banks and a negative (or positive) resist for the separators; both these resists may be based upon polyimide and spin coated onto the substrate, or a fluorinated or fluorinated-like photoresist may be employed. In the example shown the cathode separators are around 5 μm in height and approximately 20 μm wide. Banks are generally between 20 μm and 100 μm in width and in the example shown have a 4 μm taper at each edge (so that the banks are around 1 μm in height). The pixels of FIG. 3a are approximately 300 μm square but, as described later, the size of a pixel can vary considerably, depending upon the intended application.

Techniques for the deposition of material for organic light emitting diodes (OLEDs) using ink jet printing techniques are described in a number of documents including, for example, T. R. Hebner, C. C. Wu, D. Marcy, M. H. Lu and J. C. Sturm, “Ink-jet Printing of doped Polymers for Organic Light Emitting Devices”, Applied Physics Letters, Vol. 72, No. 5, pp. 519-521, 1998; Y. Yang, “Review of Recent Progress on Polymer Electroluminescent Devices,” SPIE Photonics West: Optoelectronics '98, Conf. 3279, San Jose, Jan., 1998; EP 0 880 303; and “Ink-Jet Printing of Polymer Light-Emitting Devices”, Paul C. Duineveld, Margreet M. de Kok, Michael Buechel, Aad H. Sempel, Kees A. H. Mutsaers, Peter van de Weijer, Ivo G. J. Camps, Ton J. M. van den Biggelaar, Jan-Eric J. M. Rubingh and Eliav I. Haskal, Organic Light-Emitting Materials and Devices V, Zakya H. Kafafi, Editor, Proceedings of SPIE Vol. 4464 (2002). Ink jet techniques can be used to deposit materials for both small molecule and polymer LEDs.

A volatile solvent is generally employed to deposit a molecular electronic material, with 0.5% to 4% dissolved solvent material. This can take anything between a few seconds and a few minutes to dry and results in a relatively thin film in comparison with the initial “ink” volume. Often multiple drops are deposited, preferably before drying begins, to provide sufficient thickness of dry material. Solvents which may be used include cyclohexylbenzene and alkylated benzenes, in particular toluene or xylene; others are described in WO 00/59267, WO 01/16251 and WO 02/18513; a solvent comprising a blend of these may also be employed. Precision ink jet printers such as machines from Litrex Corporation of California, USA are used; suitable print heads are available from Xaar of Cambridge, UK and Spectra, Inc. of NH, USA. Some particularly advantageous print strategies are described in the applicant's UK patent application number 0227778.8 filed on 28^{th} November 2002.

Inkjet printing has many advantages for the deposition of materials for molecular electronic devices but there are also some drawbacks associated with the technique. As previously mentioned the photoresist banks defining the wells have until now tapered to form a shallow angle, typically around 15°, with the substrate. However it has been found that dissolved molecular electronic material deposited into a well with shallow edges dries to form a film with a relatively thin edge. FIGS. 4a and 4b illustrate this process.

FIG. 4a shows a simplified cross section 400 through a well 308 filled with dissolved material 402, and FIG. 4b shows the same well after the material has dried to form a solid film 404. In this example the bank angle is approximately 15° and the bank height is approximately 1.5 μm. As can be seen a well is generally filled until it is brimming over. The solution 402 has a contact angle 0° with the plasma treated bank material of typically between 30° and 40° for example around 35°; this is the angle the surface of the dissolved material 402 makes with the (bank) material it contacts, for example angle 402a in FIG. 4a. As the solvent evaporates the solution becomes more concentrated and the surface of the solution moves down the tapering face of a bank towards the substrate; pinning of the drying edge can occur at a point between the initially landed wet edge and the foot of the bank (base of the well) on the substrate. The result, shown in FIG. 4b, is that the film of dry material 404 can be very thin, for example of the order of 10 nm or less, in a region 404a where it meets the face of a bank. In practice drying is complicated by other effects such as the coffee ring-effect. With this effect because the thickness of solution is less at the edge of a drop than in the centre, as the edge dries the concentration of dissolved material there increases. Because the edge tends to be pinned solution then flows from the centre of the drop towards the edge by capillary effect. This effect can result in dissolved material tending to be deposited in a ring rather than uniformly. The physics of the interactions of a drying solution with a surface are extremely complicated and a complete theory still awaits development.

Another drawback of banks with a long-shallow taper is that an inkjet droplet that does not fall exactly into a well but instead lands in part on the slope of the bank can dry in place, resulting in non-uniformities in the end display.

A further problem with inkjet deposition arises when filling wells which are large compared with the size of an inkjet droplet. A typical droplet from an inkjet print head has a diameter of approximately of 30 μm in flight and the droplet grows to approximately 100 μm in diameter when it lands and wets out.

Filling a well or pixel of a similar size to a drop presents little problem as when the drop lands it spreads out and fills the well. This is illustrated in FIG. 5a which shows a well 500 for a long thin pixel of a type which is typically used in a RGB (red green blue) display. In the example of FIG. 5a the pixel has a width of 50 μm and a length of 150 μm with 20 μm wide banks (giving a 70 μm pixel pitch and a 210 μm full color pitch). Such a well can be filled by three 50 μm droplets 502a, b, c as shown. Referring now to FIG. 5b this shows a well 510 for a pixel which is approximately four times larger than each dimension giving a pixel width of approximately 200 μm, more suitable for applications such as a color television. As can be seen from the figure, many droplets 512 are needed to fill such a pixel. In practice, these tend to coalesce to form a larger droplet 514 which tends not to properly fill corners of the pixel (although FIGS. 5a and 5b and idealised and, in practice, the corners are not generally as sharp as they are shown). One way around this problem is to sufficiently over fill the well that the dissolved material well is pushed into the corners. This can be achieved by using a large number of dilute droplets and a high barrier around the well. Techniques for depositing large volumes of liquid are described in WO03/065474, which describes the use of very high barriers (for examples at page 8 lines 8 to 20) to allow the wells to hold a large volume of liquid without the liquid overflowing to adjacent wells. However such structures cannot easily be formed by photolithography and instead a plastic substrate is embossed or injection moulded. It is also desirable to be able to fill a well using fewer (higher concentration) droplets as this enables, inter alia faster printing.

### GENERAL DESCRIPTION OF THE INVENTION

According to a first aspect of the invention there is therefore provided a method of fabricating a molecular electronic device, the method comprising: fabricating a substrate having a plurality of banks defining wells for the deposition of molecular material; and depositing into said wells a composition comprising a molecular electronic material dissolved in a solvent, using a droplet deposition technique, to fabricate said device; wherein a said bank has a face, defining an edge of said well, at an angle to a base of the well of greater than a contact angle of said composition with said bank face; and wherein a height of a said bank above a said base of a said well is less than 2 μm, and more preferably less than 1.5 μm.

In another aspect the invention therefore provides a method of fabricating a molecular electronic device, the method comprising: fabricating a substrate having a plurality of banks defining wells for the deposition of molecular material; and into said wells a composition comprising a molecular electronic material dissolved in a solvent, using a droplet deposition technique, to fabricate said device; wherein a said bank has a face, defining an edge of said well, at an angle to a base of the well of greater than a contact angle of said composition with said bank face; and wherein said method further comprises determining a number of droplets to deposit into a said well taking account of a tendency for said dissolved material to be drawn along a said bank face by surface wetting.

In embodiments angling the face of a bank at greater than the contact angle of the composition in which the molecular electronic material is dissolved, the dissolved material is drawn along the bank face, thus helping to fill the well and the number of droplets to deposit can then be determined taking this into account. More particularly a reduced number of droplets with a higher concentration of material may be employed to provide a film of a given dry thickness than when a bank is angled at less than the contact angle of the composition. The method may include depositing at least one droplet of dissolved material such that when it lands it spreads out and touches a bank face and is thus drawn along a well edge, for example towards a corner. Alternatively however droplets may simply be deposited into a middle of a well until a pool grows sufficiently to touch a bank face whereupon the solvent is again drawn along a bank face and towards the corner of a well. Preferably the height of a bank on the substrate, or more particularly over an electrode layer such as an anode layer is therefore less than 2 μm, more preferably less than 1.5 μm, or 1.0 μm.

Preferably the banks are formed from photoresist. A single layer of photoresist, in particular negative photoresist may be employed. The photoresist may be patterned by any conventional lithographic procedure for example, using a mask or direct-write technology.

Thus in a further aspect the invention provides a method of fabricating a molecular electronic device, the method comprising: fabricating a substrate having a plurality of banks defining wells for the deposition of molecular material; and into said wells a composition comprising a molecular electronic material dissolved in a solvent, using a droplet deposition technique, to fabricate said device; wherein a said bank has a face, defining an edge of said well, at an angle to a base of the well of greater than a contact angle of said composition with said bank face; and wherein said method further comprises lithographically forming said banks from photoresist.

In preferred embodiments of the above described methods a bank face angle is at least 40° or 50° and may be up to 90° or, in some embodiments, greater than 90°. Angles greater than 90° correspond to a bank face which is undercut, over hanging the base of the well. This is a particularly preferred arrangement because of the behaviour of the solvent in the vicinity of such a structure (described in more detail later) which, broadly speaking, draws the solvent into and onto the overhang without removing excessive quantities of solvent from the middle of a well.

In a further aspect of the invention there is therefore provided a method of fabricating a molecular electronic device, the method comprising: fabricating a substrate having a plurality of banks defining wells for the deposition of molecular material; and depositing into said wells a composition comprising a molecular electronic material dissolved in a solvent, using a droplet deposition technique, to fabricate said device; wherein a said bank has a face, defining an edge of said well, at an angle to a base of the well of at least 40° ; and wherein a height of a said bank above a said base of a said well is less than 2 μm, and more preferably less than 1.5 μm. Preferably, the angle is at least 50°. The angle may be up to 90° or, in some embodiments, greater than 90°.

In a first related aspect the invention further provides a method as claimed in any preceding claim wherein said depositing comprises depositing droplets which, on deposition, incompletely fill a said well in a lateral plane of said substrate.

In a second related aspect the invention provides a substrate for a molecular electronic device, the substrate having a plurality of banks defining wells for the deposition of molecular electronic material, wherein a said bank has a face, defining an edge of a said well, at an angle to a base of said well, of greater than 30 degrees, and wherein a height of said bank above a said base of said well is less than 2 μm, and more preferably less than 1.5 μm.

The invention also provides a method of fabricating a molecular electronic device, the method comprising: fabricating a substrate having a plurality of banks defining wells for the deposition of molecular material; and depositing into said wells a composition comprising a molecular electronic material dissolved in a solvent, using a droplet deposition technique, to fabricate said device; wherein a said bank has a face, defining an edge of said well, at an angle to a base of the well of greater than a contact angle of said composition with said bank face; and wherein said method further comprises depositing droplets of dissolved molecular electronic material into a said well such that they incompletely cover the base of the well and are spread to cover the base of the well by capillary action.

These techniques are advantageous when filling relatively large pixels, that is pixels with lateral dimensions greater than a droplet diameter. In particular there is a well Perimeter/Area (P/A) ratio effect whereby above a threshold ratio or limit, that is for a larger perimeter, a positively angled bank sidewall will provide enough “wicking” to wet the ink out along the edges (rather than needing an undercut bank). The particular P/A ratio needed for a given positive bank/sidewall angle depends upon the materials and solvents employed and upon the deposition and drying conditions and can be determined by routine experiment. More particularly the main parameters to be taken into account are the contact angle of the ink being printed and the ink drying rate (viscosity change and evaporation rate balance); other parameters include print temperature, drying temperature, drying vacuum rate, and the like, and the extent of “coffee-ringing” (more coffee-ringing implying that a lower P/A ratio is acceptable to achieve reliable complete filling). Broadly speaking, however, higher bank angles require a lower P/A ratio for wicking into the corners and hence substantially complete well filling.

Thus in another aspect the invention provides a method of fabricating a molecular electronic device, the method comprising: fabricating a substrate having a plurality of banks defining wells for the deposition of molecular material, a said well having a well base area and a well perimeter, a said bank having a face, defining an edge of a said well, at an angle to a base of the well; and depositing molecular electronic material into said wells, dissolved in a solvent, using a droplet deposition technique, to fabricate said device; wherein said bank angle and a ratio of said well perimeter to said well base area are selected such that a droplet deposited on or adjacent a said well edge is spread by wicking along said well edge.

Preferably the molecular electronic device comprise an organic light emitting diode-display device. The solvents in the above described methods may then comprise an organic or apolar solvent, for example benzene-based solvents, and the banks may have a hydro-phobic, for example fluorinated, surface.

### BRIEF DESCRIPTION OF THE DRAWINGS

These and other aspects of the present invention will now be further described, by way of example only, with reference to the accompanying figures in which:

FIG. 1 shows a vertical cross section through an example of an OLED device;

FIG. 2 shows a view from above of a portion of a three color pixelated OLED display;

FIGS. 3a and 3b show a view from above and a cross-sectional view respectively of a passive matrix OLED display;

FIGS. 4a and 4b show a simplified cross section of a well of an OLED display substrate filled with, respectively, dissolved material, and dry material;

FIGS. 5a and 5b show examples of filling a small pixel and a large pixel respectively with droplets of dissolved OLED material;

FIGS. 6a to 6d show examples of well-filling according to embodiments of the invention; and

FIGS. 7a to 7e show, respectively, an illustrating of surface forces for a liquid droplet on a solid surface, and a set of figures showing effects of progressively increasing the angle a bank face makes with a substrate.

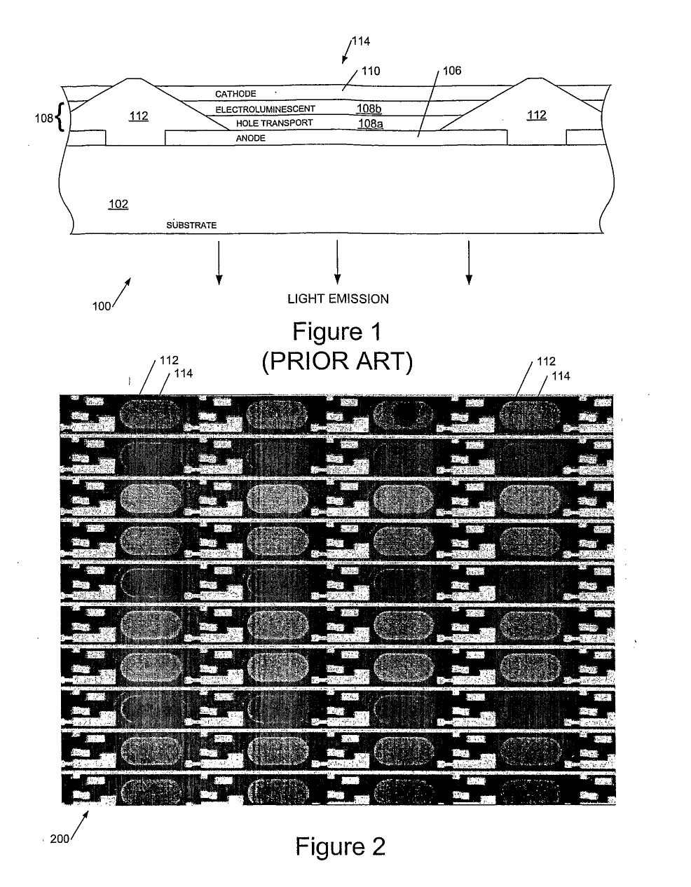

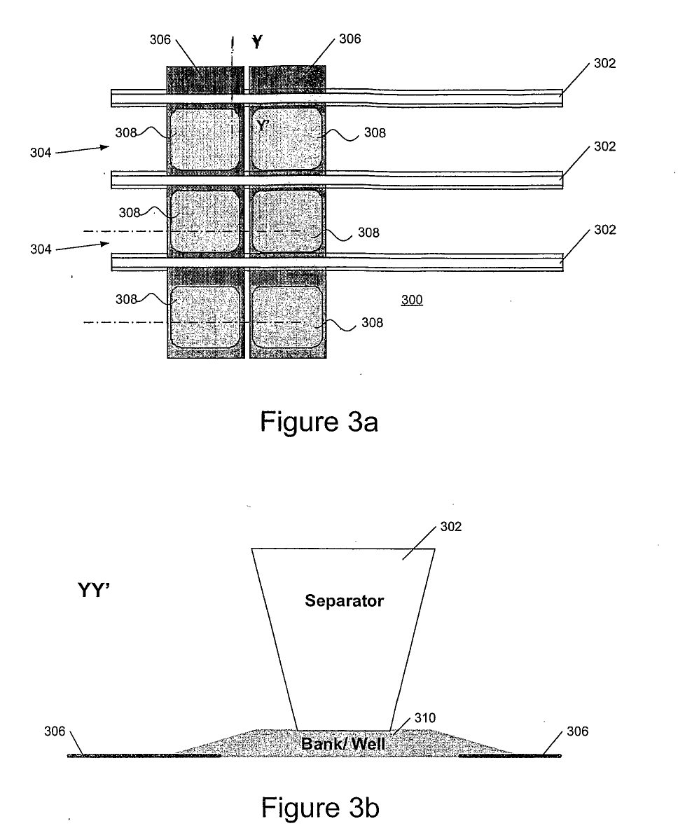

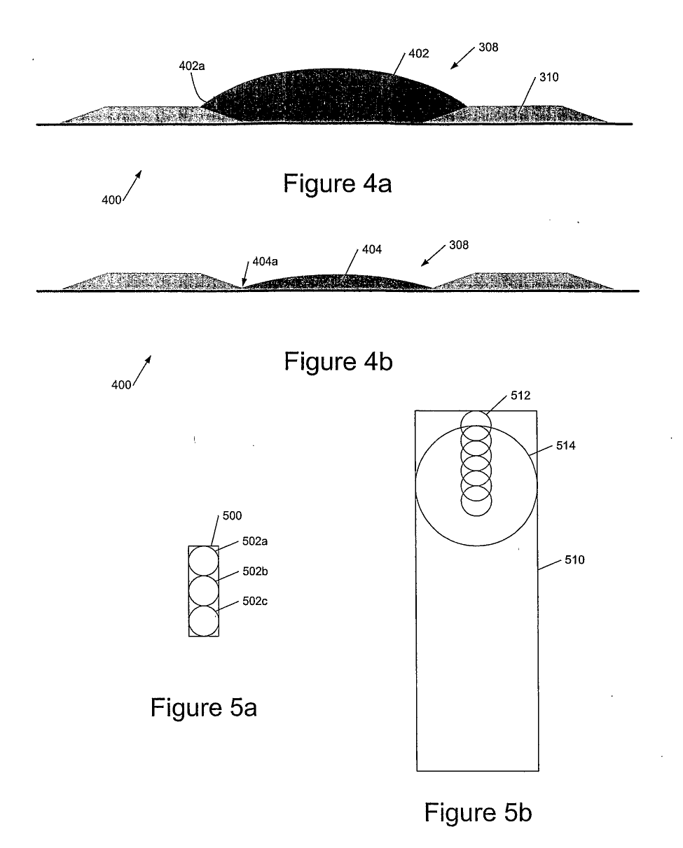

### DETAILED DESCRIPTION

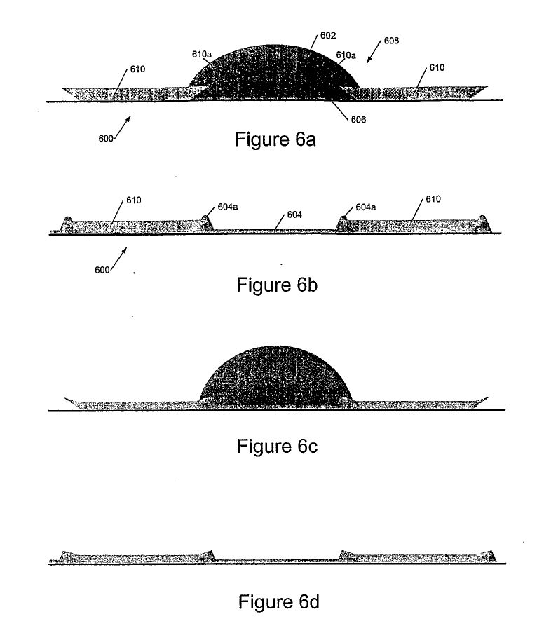

Referring now to FIG. 6a, this shows a simplified vertical cross-section through a well 608 of a substrate 600 according to an embodiment of the present invention. The substrate includes an anode layer 606 on which are formed banks 610, faces 610a of the banks defining wall of well 608. As can be seen the faces 610a of banks 610 overhang the base of the well 608. In the substrate 600 of FIG. 6a the bank angle is approximately 135°, that is −45° and height of a bank is approximately 0.6 μm. In FIG. 6a the well is filled with a solution 602 of OLED material which, in this example, brims over the top of the well and forms a contact angle of approximately 35° with the top surface of a bank. FIG. 6b shows the same substrate and well after the solvent has evaporated to leave a dry film 604 with the material together with small deposits on the tops of the banks adjacent the well-defining faces.

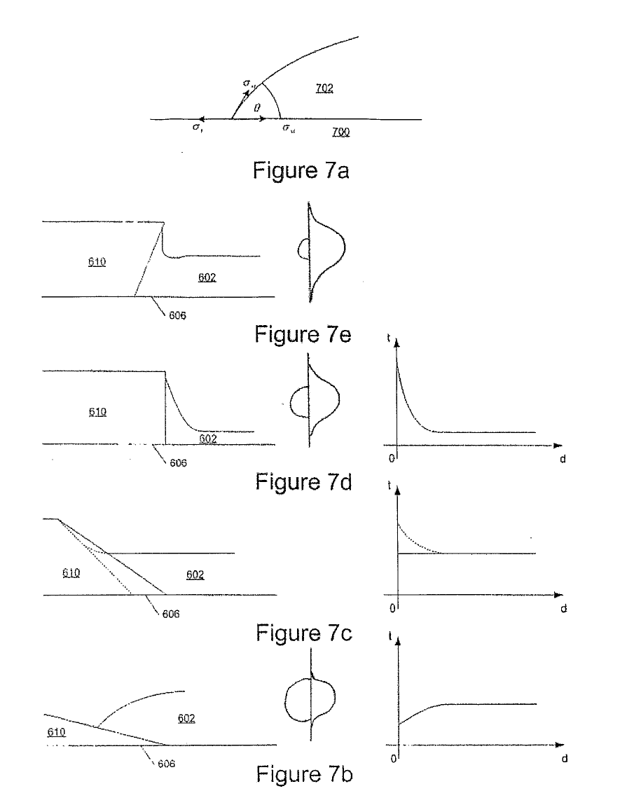

As can be seen from FIGS. 6a and 6b the capillary force around the pixel well edge pulls the ink 602 into the edges of the well, also giving good wetting into the well corners (not shown in FIGS. 6a and 6b) albeit with a slight ink overspill. Furthermore inaccurately placed droplets which land across the bank tend to be drawn into the well rather than drying on the bank. These effects are achieved with bank angles which are greater than the contact angle of the inkjet droplet. In practice this means angles of 40° or more, that is steep “positive” angles and “negative” angles. The degree to which fluid is pulled towards to the edges of a well depends upon the angle of the bank, the viscosity of the fluid, and the contact angle of the fluid with the bank. A suitable angle can be determined by routine experiment, fabricating a range of wells with different bank face angles to see which results in the optimum performance. Generally it is desirable to obtain a substantially flat dry film 604 without too much material being drawn towards the edges of a well, thinning the film in the middle. The choice of a suitable bank face angle is described further below with reference to FIG. 7.

Referring back to FIG. 5b it can be seen that a drop 514 of dissolved material formed from a plurality of smaller droplets, once it grows to touch the sides of a well, will tend to be drawn into the corners. This allows molecular electronic material to be deposited into a well by means of an incomplete filling method, that is where droplets are deposited so that they incompletely fill the well, and are then distributed to fill the well by capillary action.

To fabricate the undercut banks shown in FIGS. 6a and 6b a variety of techniques may be employed. Preferably a photodefinable polymer or photoresist such as polyimide or an acrylic photoresist is lithographically patterned using a mask or reticle and then developed to produce a desired bank face angle. Either a positive or a negative photoresist may be employed (for example there are image reversal methods which may be employed to reverse an image in a positive resist). To obtain an undercut photoresist the photoresist may be under-(or over-) exposed and overdeveloped; optionally an undercut profile may be assisted by soaking in a solvent prior to development. The skilled person will be aware that there are many variations of the basic spin, expose, bake, develop, and rinse procedure used in photolithography (see, for example, A. Reiser, Photoreactive Polymers, Wiley, New York, 1989, page 39, hereby incorporated by reference). Some particularly suitable resist materials are available from Zeon Corporation of Japan, who supply materials adapted for the fabrication of organic electroluminescent displays (negative resist materials in the ELX series, and positive resist materials in the WIX series).

The height of the resist banks 610 is preferably less than or equal to 1.2 μm, more preferably in the range 0.5 to 1.0 μm, although lower height banks, for example down to 0.45 μm or even less may be employed.

It is has been observed that at the lower end of the preferred thickness range, with undercut banks, the edge of a bank tends to turn up slightly to form a lip, as shown in FIGS. 6c and 6d, which may improve containment of ink within a well. The formation of such a lip may be related to stress relief within the bank structure.

As stated above, deposition into wells according to the methods of this invention provides improved well-filling and film drying. Each of these advantages are described in more detail below with respect to FIG. 7.

### Well Filling

FIG. 7a illustrates some of the forces which act at the edge of an interface between a solid 700 and a drop of liquid 702. The edge of the drop of liquid makes an angle θ with the surface of the solid and this angle is related to the surface tension of the liquid σₛₜ and to the solid (-vapour) surface energy (energy per unit area) σₛ and solid-liquid surface energy σₛₗ by the equation

σₛₜ cos θ+σₛₗ=σₛ Equation 1

This equation is helpful in understanding FIGS. 7b to 7e described below.

FIGS. 7b to 7e (not to scale) show effects of progressive increase bank face steepness; like elements of FIG. 6 are indicated by like reference numerals. For each figure the left hand diagram illustrates a vertical cross section through a bank face forming the edge of a well containing dissolved molecular material 602. The centre diagram depicts the configuration of a drop straddling the bank edge, that is half on the bank face and half on the underlying anode.

Referring first to FIG. 7b, this shows a bank having an angle of approximately 15° to the underlying substrate, the liquid drop contacting the face of the bank at approximately 35°. Where a drop straddles the bank edge, one of the factors affecting the extent to which the drop is drawn into the well is the angle of the bank to the substrate. At shallow bank angles, the contact area between the bank face and the drop edge is relatively small. Consequently, there is a relatively small driving force for driving the drop from the low surface energy bank material and onto the higher surface energy well base.

As the steepness of the bank face increases there is an increase in the contact surface area between the bank face and the drop edge, and consequently an increase in the driving force for drawing material off the bank and into the well. This is illustrated by the central diagram in FIGS. 7d and 7e.

FIG. 7e shows a bank 610 with an undercut or overhanging face. This arrangement provides a particularly high contact area for the drop edge on bank face and in consequence substantially all of a drop straddling the bank and base of the well is drawn into the well. In the example shown in FIG. 7e the face is at an angle of −35°, that is tilted away from the vertical by an angle substantially equal to the contact angle of the solvent, although it will be appreciated that other negative or undercut angles give similar effects.

### Film Drying

The effect of bank angle on film drying for a drop located within a well is illustrated by the right hand diagrams of FIGS. 7b-7e.

As shown in FIG. 7b, a shallow positive bank angle results in thickness of the dry film diminishing towards the bank. The inventors have found that this edge thickness may diminish to zero, resulting in a short between the anode and the cathode and a dim or missing pixel.

FIG. 7c shows a bank with a face at substantially the same angle as the contact angle of the solvent 602, resulting in a substantially flat film as can been seen from the thickness-distance graph. The effect of gradually increasing the angle of the bank face is shown by the dashed lines, this tending to pull the solvent up adjacent the bank face resulting in an increase in dry film thickness adjacent the face and a decrease elsewhere.

FIG. 7d illustrates a bank face that is at 90° to the substrate. Here a significant volume of the dissolved material is drawn up adjacent to the bank face.

Thus the dry film thickness depends upon the height of the bank, the bank angle, the solvent evaporation (drying stage) conditions and the extent of any coffee-ring effect (also affected by the ink formulation, for example the solid content and molecular weight) and can be determined by experiment (for example by preparing films under a range of conditions thickness-distance graphs using an interferometer, for example from Zygo Corporation of Connecticut, USA. Referring to the centre diagram of FIG. 7e it can also be seen that there is a significant tendency for solvent carrying dissolved material to be drawn out from the sides of the drop along the undercut of the bank face, which is useful for obtaining substantially complete well-filling from incomplete or partial filling of a well by droplet deposition. Referring to equation 1 above and to FIG. 7a, broadly speaking in the “ears”. of the droplet θ is reduced so that cos θ increases, effectively reducing the surface tension pulling the drop towards a more rounded shape.

The skilled person will recognized that the above described techniques are not limited to use in the fabrication of organic light emitting diodes (small molecules or polymer) but may be employed in the fabrication of any type of molecular electronic device in which material is dissolved in a solvent and deposited by a droplet deposition technique. No doubt many effective alternatives will occur to the skilled person and it will be understand that the invention is not limited to the described embodiments encompasses modifications apparent to those skilled in the art lying within the scope of the claims appended hereto.

1. A method of fabricating a molecular electronic device, the method comprising:
fabricating a substrate having a plurality of banks defining wells for the deposition of molecular material; and
depositing into said wells a composition comprising a molecular electronic material dissolved in a solvent, using a droplet deposition technique, to fabricate said device;
wherein a said bank has a face, defining an edge of said well, at an angle to a base of the well of greater than a contact angle of said composition with said bank face; and
wherein a height of a said bank above a said base of a said well is less than 2 μm.

2. A method as claimed in claim 1 wherein a height of a said bank above a said base of a said well is less than 1 μm.

3. A method of fabricating a molecular electronic device, the method comprising:
fabricating a substrate having a plurality of banks defining wells for the deposition of molecular material; and
depositing into said wells a composition comprising a molecular electronic material dissolved in a solvent, using a droplet deposition technique, to fabricate said device;
wherein a said bank has a face, defining an edge of said well, at an angle to a base of the well of greater than a contact angle of said composition with said bank face; and
wherein said method further comprises determining a number of droplets to deposit into a said well taking account of a tendency for said dissolved material to be drawn along a said bank face by surface wetting.

4. A method as claimed in claim 3 further comprising depositing at least one droplet of dissolved molecular electronic material such that on deposition it spreads to touch a said bank face.

5. A method as claimed in claim 3 wherein a height of a said bank above a said base of a said wall is less than 2 μm.

6. A method as claimed in claim 1 further comprising lithographically forming said banks from a photoresist.

7. A method of fabricating a molecular electronic device, the method comprising:
fabricating a substrate having a plurality of banks defining wells for the deposition of molecular material; and
depositing into said wells a composition comprising a molecular electronic material dissolved in a solvent, using a droplet deposition technique, to fabricate said device;
wherein a said bank has a face, defining an edge of said well, at an angle to a base of the well of greater than a contact angle of said composition with said bank face; and
wherein said method further comprises lithographically forming said banks from photoresist.

8. A method as claimed in claim 7 wherein said photoresist comprises a single layer of negative photoresist.

9. A method as claimed claim 1 wherein a said bank face angle is at least 40 degrees.

10. A method as claimed in claim 1 wherein a said bank face is undercut.

11. A method as claimed in claim 1 wherein said depositing step comprises depositing droplets which, on deposition, incompletely fill a said well in a lateral plane of said substrate.

12. A substrate for a molecular electronic device, the substrate having a plurality of banks defining wells for the deposition of molecular electronic material, wherein a said bank has a face, defining an edge of said well, at an angle to a base of the well of greater than 40 degrees, and wherein said bank is lithographically formed from photoresist.

13. A substrate as claimed in claim 12 wherein a height of a said bank above a base of a said well is less than 2 μm.

14. A substrate for a molecular electronic device, the substrate having a plurality of banks defining wells for the deposition of molecular electronic material, wherein a said bank has a face, defining an edge of a said well, at an angle to a base of said well, of greater than 30 degrees, and wherein a height of said bank above a said base of said well is less than 2 μm.

15. A substrate as claimed in claim 14 wherein said bank is lithographically formed from photoresist.

16. A substrate as claimed in claimed in claim 12 wherein said photoresist comprises a single layer of preferably negative photoresist.

17. A substrate as claimed in claim 12 wherein a said bank face angle is greater than 40 degrees.

18. A substrate as claimed in claim 12 wherein a said bank face angle is undercut.

19. A molecular electronic device including the substrate of claim 12.

20. A method as claimed in claim 1 wherein said molecular electronic device comprises an organic light emitting diode device.

21. A method of fabricating a molecular electronic device, the method comprising:
fabricating a substrate having a plurality of banks defining wells for the deposition of molecular material; and
depositing into said wells a composition comprising a molecular electronic material dissolved in a solvent, using a droplet deposition technique, to fabricate said device;
wherein a said bank has a face, defining an edge of said well, at an angle to a base of the well of greater than a contact angle of said composition with said bank face; and
wherein said method further comprises depositing droplets of dissolved molecular electronic material into a said well such that they incompletely cover the base of the well and are spread to cover the base of the well by capillary action.

22. A method of fabricating a molecular electronic device, the method comprising:
fabricating a substrate having a plurality of banks defining wells for the deposition of molecular material, a said well having a well base area and a well perimeter, a said bank having a face, defining an edge of a said well, at an angle to a base of the well; and
depositing molecular electronic material into said wells, dissolved in a solvent, using a droplet deposition technique, to fabricate said device;
wherein said bank angle and a ratio of said well perimeter to said well base area are selected such that a droplet deposited on or adjacent a said well edge is spread by wicking along said well edge.

23. A method as claimed in claim 22 wherein deposition into a corner of a said well occurs by wicking.

24. A method as claimed in claim 1 wherein a height of a said bank above a said base of a said well is less than 1.5 μm

25. A method as claimed in claim 3 wherein a height of a said bank above a said base of a said well is less than 1.5 μm

26. A method as claimed in claim 3 further comprising lithographically forming said banks from a photoresist.

27. A method as claimed claim 3 wherein a said bank face angle is at least 40 degrees.

28. A method as claimed claim 7 wherein a said bank face angle is at least 40 degrees.

29. A method as claimed in claim 3 wherein a said bank face is undercut.

30. A method as claimed in claim 7 wherein a said bank face is undercut.

31. A method as claimed in claim 3 wherein said depositing step comprises depositing droplets which, on deposition, incompletely fill a said well in a lateral plane of said substrate

32. A method as claimed in claim 7 wherein said depositing step comprises depositing droplets which, on deposition, incompletely fill a said well in a lateral plane of said substrate

33. A substrate as claimed in claim 12 wherein a height of a said bank above a base of a said well is less than 1.5 μm.

34. A substrate as claimed in claim 14, wherein a height of a said bank above a said base of a said well is less than 1.5 μm.

35. A substrate as claimed in claimed in claim 13 wherein said photoresist comprises a single layer of preferably negative photoresist.

36. A substrate as claimed in claimed in claim 15 wherein said photoresist comprises a single layer of preferably negative photoresist.

37. A substrate as claimed in claim 14 wherein a said bank face angle is greater than 40 degrees.

38. A substrate as claimed in claim 14 wherein a said bank face angle is undercut.

39. A molecular electronic device including the substrate of claim 14.

40. A method as claimed in claim 3 wherein said molecular electronic device comprises an organic light emitting diode device.

41. A method as claimed in claim 7 wherein said molecular electronic device comprises an organic light emitting diode device.

42. A substrate as claimed in claim 12 wherein said molecular electronic device comprises an organic light emitting diode device.

43. A method as claimed in claim 14 wherein said molecular electronic device comprises an organic light emitting diode device.

44. A device as claimed in claim 19 wherein said molecular electronic device comprises an organic light emitting diode device.
